(19) United States
(12) Patent Application Publication
(10) Pub. No.: US 2026/0341344 A1
(43) Pub. Date: Oct. 29, 2026

(54) MEMORY DEVICE WITH A TRACKING MECHANISM

(71) Applicant: Taiwan Semiconductor Manufacturing Company, Ltd., Hsinchu (TW)

(72) Inventors: Chien-Yuan CHEN, Hsinchu (TW); Hau-Tai SHIEH, Hsinchu (TW); Cheng Hung LEE, Hsinchu (TW)

(21) Appl. No.: 19/188,897

(22) Filed: Apr. 24, 2025

(51) Int. Cl. G11C 11/419; G11C 5/06; G11C 11/418

(52) U.S. Cl. CPC G11C 11/419; G11C 5/063; G11C 11/418

(57) ABSTRACT

A memory device with a tracking mechanism is provided. The memory device includes memory array having a bit line and a memory cell coupled to the bit line. The memory device further includes a sense amplifier coupled to the bit line and a tracking bit line. A driver circuit controls a voltage on the tracking bit line. A control circuit is connected to the tracking bit line. The control circuit is configured to generate a strobe signal for enabling the sense amplifier in accordance with the voltage on the tracking bit line.

### BACKGROUND

Static Random-Access Memories (SRAMs) are semiconductor elements widely applied in modern computing devices. A typical SRAM memory device has an array of memory cells. Each memory cell uses six transistors, for example, connected between an upper reference potential and a lower reference potential (typically ground) such that one of two storage nodes can be occupied by the information to be stored, with the complementary information stored at the other storage node. For the efficiency of operation, a “self-timed” SRAM is developed, which controls timing independently of the externally generated clock signal. In a self-timed SRAM design, in order to generate enough bit line differential voltage values for robustly reading out sensing results, a bit cell tracking design is applied, where a tracking bit line is used to model the bit line discharge delay of the accessed bit line and then generate sense amplifier firing and word line falling edges.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is diagram illustrating a memory device in accordance with some embodiments.

FIG. 2 is diagram illustrating a memory cell of the memory device of FIG. 1 in accordance with some embodiments.

FIG. 3 is a diagram illustrating further aspects of the memory device of FIG. 1 in accordance with some embodiments.

FIG. 4A-4D are diagrams illustrating a tracking word line select circuits in accordance with some embodiments.

FIG. 5 is a diagram illustrating further aspects of the memory device of FIG. 1 in accordance with some embodiments.

FIG. 6A is timing diagram illustrating example waveforms for various signals of the memory device in accordance with some embodiments.

FIG. 6B is timing diagram illustrating example waveforms for tracking word line signals and SAE signals of the memory device in accordance with some embodiments.

FIG. 7A is a graph illustrating a clock to data delay and a read margin for different operation modes of the memory device.

FIG. 7B is a graph illustrating a cycle time and a write margin for different operation modes of the memory device.

FIG. 8 is a flow diagram of a method for performing a read operation in a memory device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

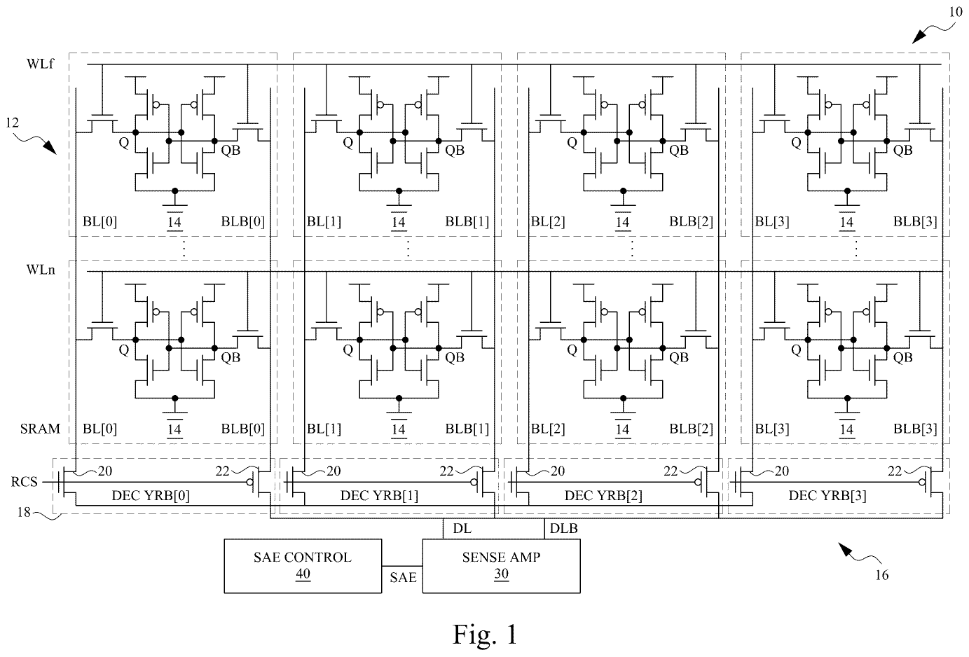

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Further, when a first element is described as being “connected” or “coupled” to a second element, such description includes embodiments in which the first and second elements are directly connected or coupled to each other, and also includes embodiments in which the first and second elements are indirectly connected or coupled to each other with one or more other intervening elements in between The disclosure provides flexible tuning schemes for different operation modes of a memory device for read and write operations. FIG. 1 is a diagram illustrating a memory device 10 in accordance with various embodiments. In one example, memory device 10 is a Static Random Access Memory (SRAM), though the SRAM is used for illustration. Other types of memories are within the scope of the disclosure. As shown in FIG. 1, memory device 10 includes a memory cell array 12 with an array of memory cells 14. Memory cells 14 (also referred to as bit cells) are arranged in a column-row configuration in which each column has a bit line (also referred to as bit line BL or BL) and a bit line bar (also referred to as bit line bar BLB or BLB). For illustrative purposes, array 12 shown in FIG. 1 has four columns and thus four sets of bit lines BL[0-3] and bit line bars BLB[0-3]. Each row of array 12 has a word line WLf-WLn (collectively word lines WL).

The bit line BL and the bit line bar BLB of each column are respectively coupled to a plurality of memory cells that are disposed in that column, and each memory cell 14 in that column is arranged on a different row and coupled to a respective (different) word line WLf-WLn. That is, each memory cell 14 of array 12 is coupled to a bit line pair BL/BLB of a column of array 12 and a word line WLf-WLn of a row of array 12. The word lines WLf-WLn are connected to a word line driver circuit (not shown) that output a row, or word line select signal. In some embodiments, the bit lines BL/BLB are arranged in parallel vertically and the word lines WLf-WLN are arranged in parallel horizontally (i.e., perpendicular to the bit lines BL/BLB).

The bit lines BL/BLB of each column are coupled to an I/O circuit 16 that includes a column select circuit 18 and a sense amplifier 30. Column select circuit 18 receives a column select signal RCS to select a column of array 12 to read or write data. The bit lines BL/BLB of the selected column are connected to sense amplifier 30 by data lines DL and DLB. A Sense Amplifier Enable (SAE) control circuit 40 outputs a SAE signal (also referred to as a strobe signal) to sense amplifier 30, in response to which sense amplifier 30 outputs data read from array 12. As will be discussed further below, SAE control circuit 40 is configured to output the SAE signal based on a determined operation mode for the read or write operation.

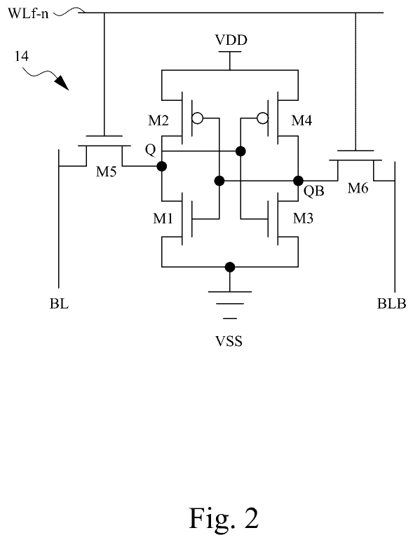

As noted above, in some embodiments memory device 10 is an SRAM memory, and thus array 12 is an array of SRAM memory cells 14. Other memory types are within the scope of the disclosure. FIG. 2 illustrates further aspects of the memory device 10, including an example of a memory cell 14 of array 12 shown in FIG. 1. Memory cell 14 is connected to one of the word lines WLf-WLn and a pair of the complementary bit lines BL and BLB.

Memory cell 14 includes p-channel Metal Oxide Semiconductor (PMOS) transistors M2, M4 and n-channel Metal Oxide Semiconductor (NMOS) transistors M1, M3, M5, M6. The transistors M1-M6 include source/drain (S/D) terminals and a gate terminal. As used herein, the S/D terminals generally may refer to a source or a drain, individually or collectively dependent upon the context. The transistors M1 and M2 are coupled to one another and positioned between the supply voltage VDD and ground to form a first inverter. Similarly, the transistors M3 and M4 are coupled between VDD and ground to form a second inverter. The two inverters are cross-coupled to each other. The cross coupled inverters of memory cell 14 provide two stable voltage states denoting logic values 0 and 1.

An access transistor M5 connects the output Q of the first inverter to the bit line BL. Similarly, the access transistor M6 connects the output QB of the second inverter to the bit line bar BLB. The word line WL is attached to the gate terminals of the access transistors M5 and M6 to selectively couple the outputs of the inverters to the bit lines BL/BLB during read/write operations in response to the word line signal WL from the word line driver. In a read operation, for example, the bit lines BL/BLB are pre-charged to a predefined voltage. When the word line is enabled, the data lines DL/DLB connect the selected bit lines BL/BLB to sense amplifier 30, which senses and outputs the stored information. In some embodiments more or fewer than 6 transistors may be used to implement memory cell 14.

Referring back to FIG. 1, column select circuit 18 is configured to select a column with memory cells 12 to be accessed based on a decoded column address provided from a column decoder which, in one or more embodiments, is included in a memory controller. The bit lines BL/BLB of the selected column are connected to the data lines DL/DLB by column select circuit 18. In some disclosed examples, column select circuit 18 includes a plurality of PMOS transistors 20 having one S/D terminal connected to a respective one of the bit lines BL and the other S/D terminal connected to the data line DL, and another plurality of PMOS transistors 22 having one S/D terminal connected to a respective one of the bit lines bar BLB and the other S/D terminal connected to the data line bar DLB. Gate terminals of the transistors 20, 22 receive the column select signal RCS, in response to which the selected bit line BL and bit line bar BLB are connected respectively to the data line DL and data line bar DLB.

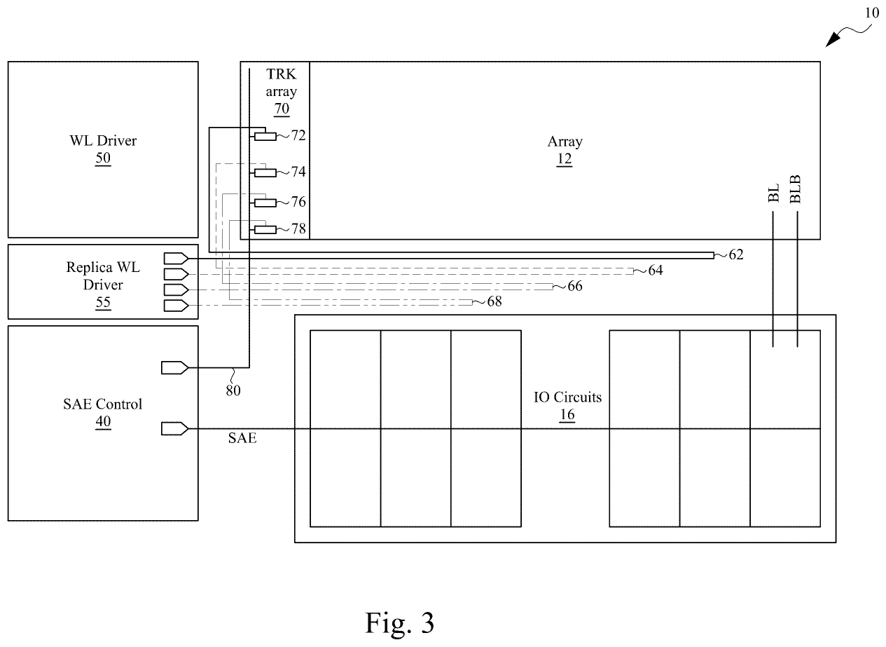

FIG. 3 illustrates further aspects of memory device 10. As shown in FIG. 3, memory device 10 further includes a word line driver circuit 50, a replica word line driver circuit 55, and a plurality of tracking word lines, for example, a first tracking word line 62, a second tracking word line 64, a third tracking word line 66, and a fourth tracking word line 68. Memory device 10 further includes a tracking array 70. Tracking array 70 includes a plurality of replica memory cells, for example, a first number of replica memory cells 72, a second number of replica memory cells 74, a third number of replica memory cells 76, and a fourth number of replica memory cells 78. Each of the plurality of replica memory cells of tracking array 70 is connected to a tracking bit line 80. The replica memory cells of tracking array 70 are same as or substantially same as memory cells 14 as discussed above with reference to FIG. 2. Although memory device 10 is shown to include four tracking word lines, it can include a different number of tracking word lines.

In one example, first number of replica memory cells 72 are associated with or coupled to first tracking word line 62. In addition, second number of replica memory cells 74 are associated with or coupled to second tracking word line 64, third number of replica memory cells 76 are associated with or coupled to third tracking word line 66, and fourth number of replica memory cells 78 are associated with or coupled to fourth tracking word line 68.

Word line driver circuit 50 is configured to decode a memory address to obtain a row address and output the word line signal on the word line WLf-WLn for the appropriate row. As noted above, in a read operation the bit lines BL/BLB are pre-charged to a predefined voltage. When the word line signal is output by word line driver circuit 50, memory cell 14 of the selected column pulls down the corresponding BL/BLB voltage. When the bit line voltage is sufficiently pulled down, the SAE signal is asserted, in response to which sense amplifier 30 senses and latches the data signal on the data lines DL/DLB.

If the SAE signal is output too soon, the data signal on the data lines DL/DLB may not be sufficiently developed (i.e. signal on one of the data lines DL/DLB has not fallen sufficiently), read errors could occur. The illustrated example provides tracking array 70 to determine timing of the SAE signal. The timing of the SAE signal is determined based on a voltage of tracking bit line 80. In one example, and as discussed above, tracking array 70 includes tracking plurality of replica memory cells that are similar to memory cell 14 of array 12. The plurality of tracking word lines and tracking bit line 80 of tracking array 70 are used to monitor array 12 behavior and provide this information to SAE control circuit 40. SAE control circuit 40 generates the SAE signal based on the voltage level of tracking bit line 80.

For example, during the read operation, tracking bit line 80 is discharged, and SAE control circuit 40 detects the voltage level of tracking bit line 80 and compares the voltage level of tracking bit line 80 with a reference voltage Vref. Once the voltage level of tracking bit line 80 is pulled down below the level of the reference voltage Vref, SAE control circuit 40 generates the SAE signal enabling the corresponding sense amplifier 30. SAE control circuit 40, in one example, therefore, is a comparator. In an example, SAE control circuit 40 is implemented by using an operational amplifier as a comparator whose inverting input terminal is coupled to tracking bit line 80 and a non-inverting input terminal is configured to receive the reference voltage Vref. Once the voltage received by the inverting input terminal is discharged to a level smaller than the reference voltage Vref at the non-inverting input terminal, the operational amplifier is configured to output the SAE signal to drive sense amplifiers 30 of I/O circuit 16 to sense and latch the data signal on the data lines DL/DLB.

The SAE signal is typically asserted such that a Read Margin (RM), that is, the voltage difference between the data lines DL and DLB, at a predetermined point in the transition of the strobe signal pulse is sufficient for sense amplifier 30 to sense and latch the logic 0 and 1 data values on the data lines DL and DLB. However, this can result in reducing the overall read timing performance (also referred to as clock to data delay or Tcd), which refers to the latency timing from the beginning of a read operation to the time that valid data is available on the output.

For instance, a timing for bit line signals to develop is based on factors such as the bit line capacitance, supply voltage, memory cell current, and the like. A bit line voltage drop timing Tbldrop may be expressed as:

Tbldrop=C*V/Icell

where C is the bit line capacitance, V is the supply voltage level, and Icell is the memory cell current. Thus, based on size of memory cells and loading of bit lines, the Tbldrop may be more than desired effecting the Tcd. The disclosure provides processes to control the voltage on tracking bit line 80 to provide a different RM for different type of read modes.

In example embodiments, and as discussed in greater detail in the following sections of the disclosure, the voltage on tracking bit line 80 is controlled by enabling one the plurality of word lines, by varying a length (and therefore a resistance) of one or more of the plurality of tracking word lines, by varying a number of tracking memory cells connected to one or more of the plurality of tracking word lines, by varying a size of replica word line driver circuit 55, by varying a location of tracking memory cells connected to one or more of the plurality of tracking word lines, etc.

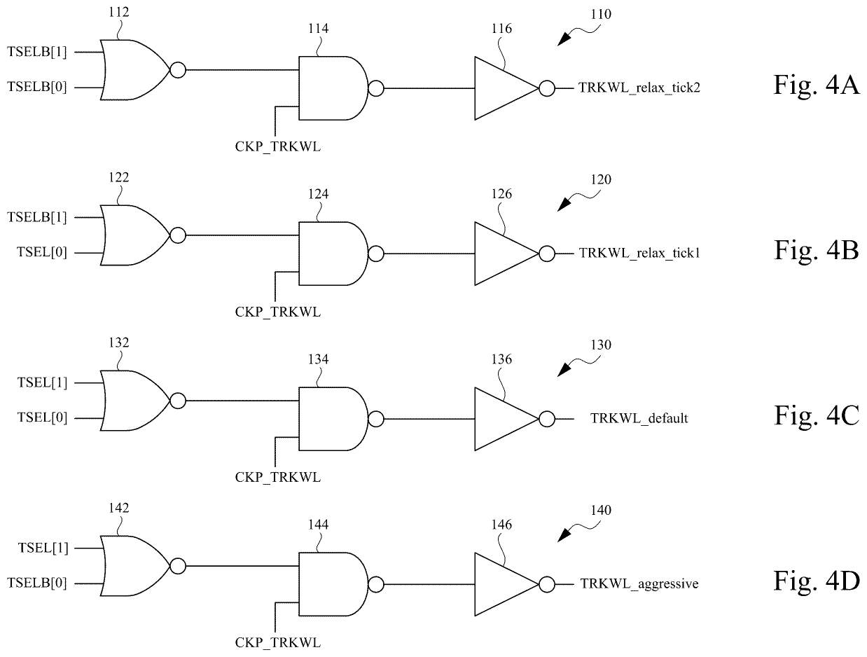

FIGS. 4A-4D illustrate example tracking world line select circuits (also referred to as tracking word line drivers) of replica word line driver 55. Replica word line driver 55 may be similar to word line driver 50 and emulates word line driver 50 behavior including a level shifter strength. The tracking word line select circuits selects one of the plurality of tracking word lines based on a selected or a desired operation mode for a read operation or a write operation in memory device 10. The one of the plurality of tracking word lines is selected based on a select signal received at the tracking world line select circuits. In some examples, the select signal is a two-bit signal having a first bit and second bit.

FIG. 4A illustrate a first tracking word line select circuit 110. First tracking world line select circuit 110 selects first tracking word line 62 for a relax tick 2 mode. In the relax tick 2 mode, both the RM and the Tcd are much higher than a default mode, however, the power consumption is much lower than the default mode. For example, first tracking word line 62 may be the longest and first number of tracking memory cells 72 connected to first tracking word line 62 may be the lowest.

As shown in FIG. 4A, first tracking word line select circuit 110 includes a first NOR logic 112, a first NAND logic 114, and a first NOT logic 116. A first input terminal of first NOR logic 112 receives an inverse of the first bit of the select signal and a second input terminal of first NOR logic 112 receives an inverse of the second bit of the select signal. An output terminal of first NOR logic 112 is connected to a first input terminal of first NAND logic 114. A second input terminal of first NAND logic 114 receives a tracking word line clock pulse (that is, CKP_TRKWL). An output terminal of first NAND logic 114 is connected to an input terminal of first NOT logic 116. An output terminal of first NOT logic 116 is connected to first tracking word line 62.

FIG. 4B illustrate a second tracking word line select circuit 120. Second tracking world line select circuit 120 selects second tracking word line 64 for a relax tick 1 mode. In the relax tick 1 mode, both the read margin and the cycle time are slightly higher than the default mode, however, the power consumption is slightly lower than the default mode. Hence, the relax tick 1 mode may fall between the relax tick 2 mode and the default mode. For example, second tracking word line 64 may be the second longest and second number of tracking memory cells 74 connected to second tracking word line 64 may be the second lowest.

As shown in FIG. 4B, second tracking word line select circuit 120 includes a second NOR logic 122, a second NAND logic 124, and a second NOT logic 126. A first input terminal of second NOR logic 122 receives an inverse of the first bit of the select signal and a second input terminal of second NOR logic 122 receives the second bit of the select signal. An output terminal of second NOR logic 122 is connected to a first input terminal of second NAND logic 124. A second input terminal of second NAND logic 124 receives a tracking word line clock pulse (that is, CKP_TRKWL). An output terminal of second NAND logic 124 is connected to an input terminal of second NOT logic 126. An output terminal of second NOT logic 126 is connected to second tracking word line 64.

FIG. 4C illustrate a third tracking word line select circuit 130. Third tracking world line select circuit 130 selects third tracking word line 66 for the default mode. As shown in FIG. 4C, third tracking word line select circuit 130 includes a third NOR logic 132, a third NAND logic 134, and a third NOT logic 136. A first input terminal of third NOR logic 132 receives a first bit of the select signal and a second input terminal of third NOR logic 132 receives the second bit of the select signal. An output terminal of third NOR logic 132 is connected to a first input terminal of third NAND logic 134. A second input terminal of third NAND logic 134 receives a tracking word line clock pulse (that is, CKP TRKWL). An output terminal of third NAND logic 134 is connected to an input terminal of third NOT logic 136. An output terminal of third NOT logic 136 is connected to third tracking word line 66.

FIG. 4D illustrate a fourth tracking word line select circuit 140. Fourth tracking world line select circuit 140 selects fourth tracking word line 68 for an aggressive mode. The aggressive mode is optimized for higher speed and performance resulting in fastest possible read access time. This minimizes latency allowing data to be accessed with minimal delay.

As shown in FIG. 4D, fourth tracking word line select circuit 140 includes a fourth NOR logic 142, a fourth NAND logic 144, and a fourth NOT logic 146. A first input terminal of fourth NOR logic 142 receives the first bit of the select signal and a second input terminal of fourth NOR logic 142 receives an inverse of the second bit of the select signal. An output terminal of fourth NOR logic 142 is connected to a first input terminal of fourth NAND logic 144. A second input terminal of fourth NAND logic 144 receives a tracking word line clock pulse (that is, CKP_TRKWL). An output terminal of fourth NAND logic 144 is connected to an input terminal of fourth NOT logic 146. An output terminal of fourth NOT logic 146 is connected to fourth tracking word line 68.

Different values of the first bit and the second bit of the select signal can be used to select different tracking word lines. For example, bits 01 can be used for the aggressive mode. When the first bit is 0 and the second logic bit is 1, an output at fourth NOR logic 142 is bit 1. Hence, an output of fourth NAND logic is an inverse of the tracking word line clock pulse (that is, CKP_TRKWL) that is provided to the input terminal of fourth NOT logic 146. This results in the output terminal of fourth NOT logic 146 powering fourth tracking word line 68.

Similarly, bits 00 can be used for the default mode, bits 10 can be used for the relax mode 1, and bits 11 can be used for the relax mode 2. A different number and a different combination of bits can be used for selecting different tracking word lines of memory device 10. In addition, the first input terminal and the second input terminal of each of first NOR logic 112, second NOR logic 122, third NOR logic 132, fourth NOR logic 142, first NAND logic 114, second NAND logic 124, third NAND logic 134, and fourth NAND logic 144 are symmetric and interchangeable.

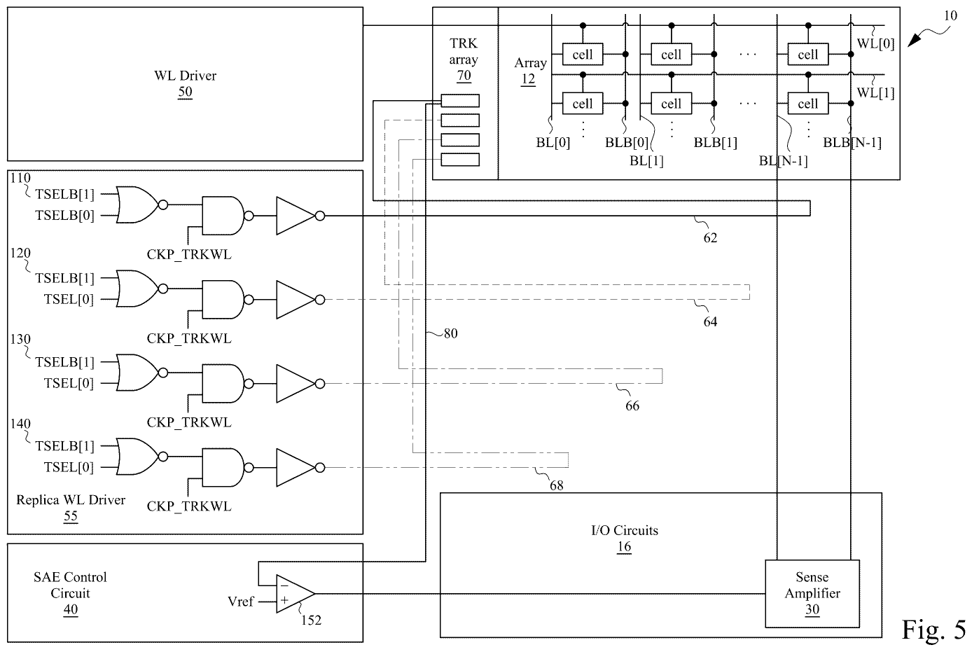

FIG. 5 is a diagram illustrating further aspects of the memory device of FIG. 1 in accordance with some embodiments. As shown in FIG. 5, first tracking word line select circuit 110 is connected to first tracking word line 62, second tracking word line select circuit 120 is connected to second tracking word line 64, third tracking word line select circuit 130 is connected to third tracking word line 66, and fourth tracking word line select circuit 140 is connected to fourth tracking word line 62. In addition, and as shown in FIG. 5, SAE control circuit 40 includes a comparator 152. A first input terminal of comparator 152 is connected to tracking bit line 80 and a second input terminal of comparator 152 is connected to a reference voltage Vref. An output terminal of comparator 153 is connected to sense amplifier 30. Comparator 152 compares the voltage on tracking bit line 80 with the reference voltage Vref and provides the SAE signal based on the comparison to sense amplifier 30.

During the read operation, a word line corresponding to a selected memory cell is charged by word line driver circuit 50. In addition, a mode of operation for memory device 10 is selected using values of the first bit and the second bit of the select signal through replica word line driver circuit 55. Based on the selected mode of operation, on of first tracking word line 62, second tracking word line 64, third tracking word line 66, and fourth tracking word line 68 is selected and charged through a corresponding tracking word line select circuit. This leads to discharge of tracking bit line 80. SAE control circuit 40 detects the voltage level of tracking bit line 80 and comparator 152 of SAE control circuit 40 compares the voltage level of tracking bit line 80 with the reference voltage Vref. Once the voltage level of tracking bit line 80 is pulled down below the level of the reference voltage Vref, comparator 152 generates the SAE signal enabling corresponding sense amplifier 30. In one example, and as shown I FIG. 5, comparator 152 is an operational amplifier with the inverting input terminal coupled to tracking bit line 80 and a non-inverting input terminal being configured to receive the reference voltage Vref. Once the voltage received by the inverting input terminal is discharged to a level smaller than the reference voltage Vref at the non-inverting input terminal, the operational amplifier is configured to output the SAE signal to drive sense amplifiers 30 of I/O circuit 16 to sense data stored in a selected memory cell.

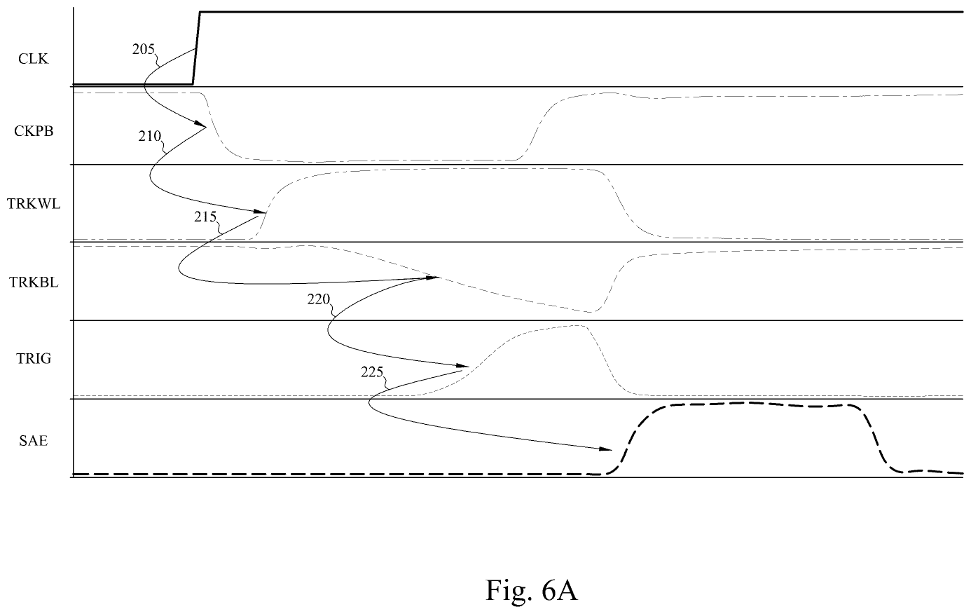

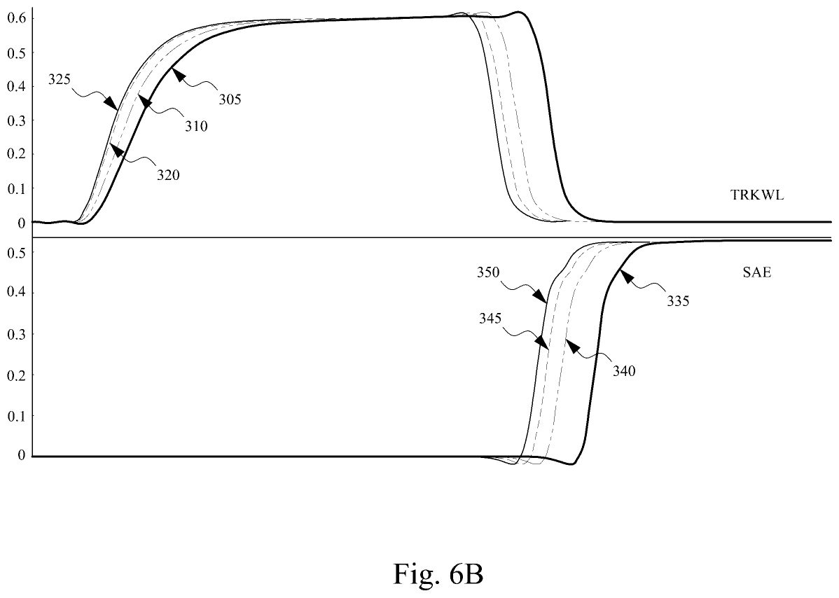

FIG. 6A is a diagram showing signals during a read operation in memory device 10 in accordance with some embodiments. A clock signal CLK is generated at a beginning or initiation of the read operation. A rising edge of the clock signal CLK causes a falling edge of a delayed clock signal CKPB, as indicated by arrow 205. In some embodiments, the clock signal CLK and the delayed clock signal CKPB are generated by a main memory control circuit.

The falling edge of the delayed clock signal CKPB causes a rising edge of a TRKWL signal (a representation a voltage on a selected tracking word line) as indicated arrow 210. The falling edge if the delayed clock signal CKPB also causes a rising edge of a WL signal (not shown). The rising edge of the TRK WL signal causes a falling edge of a TRKBL signal (a representation of a voltage on tracking bit line 80) as indicated by arrow 215. The falling edge of the TRKBL signal causes SAE control circuit 40 to generate a TRIG signal as indicated by arrow 220. The rising edge of the TRIG signal causes SAE control circuit 40 to generate the SAE signal as indicated by arrow 225. Hence, the voltage on the selected tracking word line determines or controls a timing for generating the SAE signal.

FIG. 6B is a diagram illustrating different TRKWL signals corresponding to different tracking word lines and a corresponding SAE signal. As discussed above, the voltage on tracking bit line 80 is controlled by varying a length of one or more of the plurality of tracking word lines, varying a number of tracking memory cells connected to one or more of the plurality of tracking word lines, varying a size of replica word line driver circuit 55, varying a location of tracking memory cells connected to one or more of the plurality of tracking word lines, etc. In some examples, each of the plurality of tracking word line may corresponding to a different mode of operation of memory device 10. In addition, and as discussed above the voltage on the selected tracking word line determines a timing for generating the SAE signal. Hence, by selecting a different tracking word line, the SAE signal generation time varied, thereby by varying a RM for memory device 205.

As shown in FIG. 6B, a first TRKWL signal 305 and a first SAE signal 335 correspond to first tracking word line 62 and the relax tick 2 mode. For example, first tracking word line 62 is the longest and first number of tracking memory cells 72 connected to first tracking word line 62 may be the lowest (for example, 8). This causes the rate of increase (or slope) of first TRK WL signal 305 to be the lowest, and hence first SAE signal 335 to be the most delayed. Therefore, the relax tick 2 mode may have the highest RM and the highest Tcd.

A second TRK WL signal 310 and second SAE signal 340 correspond to second tracking word line 64 and the relax tick 1 mode. Second tracking word line 64 is the second longest and second number of tracking memory cells 72 connected to second tracking word line 64 may be the second lowest (for example, 10). This causes the rate of increase (or slope) of second TRKWL signal 310 to be the second lowest (however, faster than first TRK WL signal 305), and hence second SAE signal 340 to be the second most delayed (however, less than first SAE signal 335). Therefore, the relax tick 1 mode may have the second highest RM and the second highest Tcd.

A third TRKWL signal 315 and a third SAE signal 345 correspond to third tracking word line 66 and the default mode. Third tracking word line 66 is the third longest and third number of tracking memory cells 76 connected to third tracking word line 66 may be the third lowest (for example, 12). This causes the rate of increase (or slope) of third TRKWL signal 320 to be the third lowest (however, faster than second TRKWL signal 310), and hence third SAE signal 335 to be the third most delayed (however, less than second SAE signal 340). Therefore, the default mode may have the third highest RM and the third highest Tcd.

A fourth TRKWL signal 325 and fourth SAE signal 350 correspond to fourth tracking word line 68 and the aggressive mode. Fourth tracking word line 68 is the fourth longest and fourth number of tracking memory cells 78 connected to fourth tracking word line 68 may be the fourth lowest (for example, 14). This causes the rate of increase (or slope) of fourth TRKWL signal 325 to be the fourth lowest (however, faster than third TRKWL signal 320), and hence fourth SAE signal 350 to be the fourth most delayed (however, less than third SAE signal 345). Therefore, the aggressive mode may have the fourth highest RM and the fourth highest Tcd.

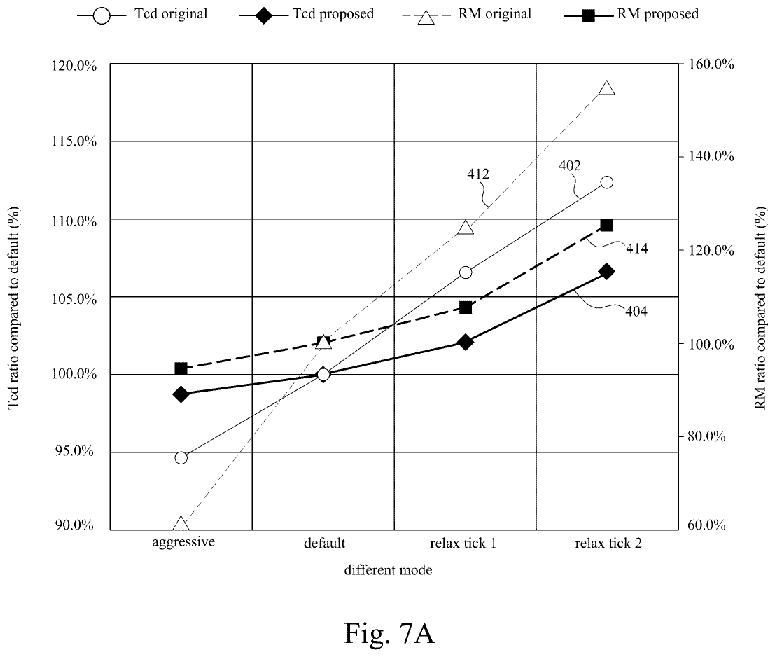

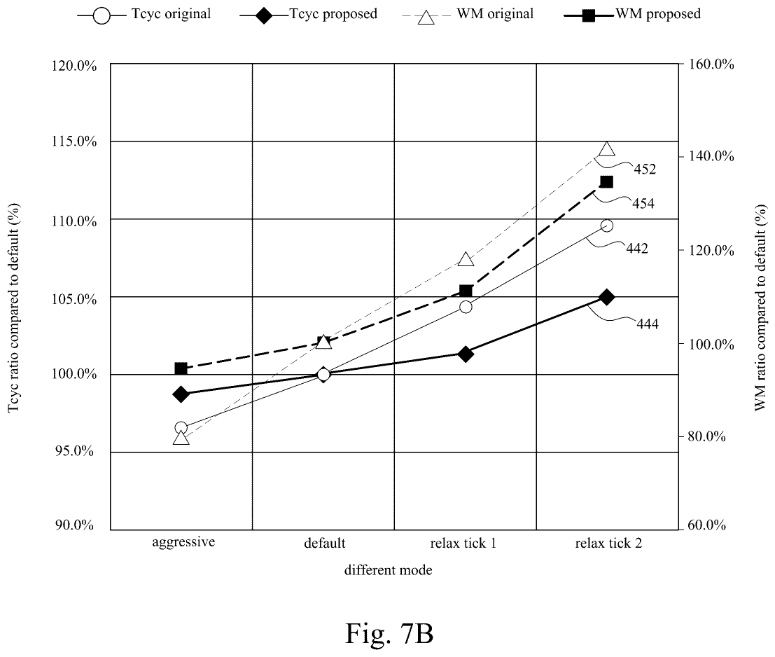

FIG. 7A is a diagram illustrating comparison of the Tcd and the RM for different modes of operation of memory device 10 with a conventional memory device. First plot 402 represents a Tcd for a conventional memory device and second plot 404 represents a Tcd for memory device 10. Third plot 412 represents a RM for a conventional memory device and fourth plot 414 represents a RM for memory device 10. As shown in FIG. 7A, a variation in the Ted for memory device 10 for different modes is less than that of a conventional memory device. For example, for a conventional memory device, the Tcd varies from 90% for the aggressive mode to 120% for the relax tick 2 mode (a change of almost 30%). On the contrary, the Tcd for memory device 10 varies from a slightly below 100% for the aggressive mode to a slightly above 105% for the relax tick 2 mode (a change of approximately 10%).

In addition, and as shown in FIG. 7A, a variation in the RM for memory device 10 for different modes is less than that of a conventional memory device. For example, for a conventional memory device, the RM varies from 60% for the aggressive mode to closer to 160% for the relax tick 2 mode (a change of almost 100%). On the contrary, the RM for memory device 10 varies from a slightly below 100% for the aggressive mode to a slightly below 120% for the relax tick 2 mode (a change of approximately 20%).

FIG. 7B is a diagram illustrating comparison of the cycle time (Tcyc) and a Write Margin (WM) for different modes of operation of memory device 10 with a conventional memory device. A first plot 442 represents the Tcyc for a conventional memory device and a second plot 444 represents a Tcyc for memory device 10. A third plot 452 represents a WM for a conventional memory device and a fourth plot 454 represents a WM for memory device 10. As shown in FIG. 7B, a variation in the Tcyc for memory device 10 for different modes is less than that of a conventional memory device. For example, for a conventional memory device, the Tcyc varies from a slightly above 95% for the aggressive mode to 110% for the relax tick 2 mode (a change of almost 25%). On the contrary, the Tcyc for memory device 10 varies from a slightly above 95% for the aggressive mode to 105% for the relax tick 2 mode (a change of approximately less than 10%).

In addition, and as shown in FIG. 7B, a variation in the WM for memory device 10 for different modes is less than that of a conventional memory device. For example, for a conventional memory device, the WM varies from a slightly above 80% for the aggressive mode to closer to 140% for the relax tick 2 mode (a change of almost 60%). On the contrary, the WM for memory device 10 varies from a slightly below 100% for the aggressive mode to a slightly close to 130% for the relax tick 2 mode (a change of approximately 30%). Hence, memory device 10 provides both a better Tcd and a better Tcyc compared to a conventional memory device.

The Tcd and Tcyc of memory device 10 can further be varied by varying a location of the plurality of replica memory cells of tracking array 70, a number of replica memory cells connected to each tracking word lines, a length of each of tracking lines, a size of replica word line driver 55, etc.

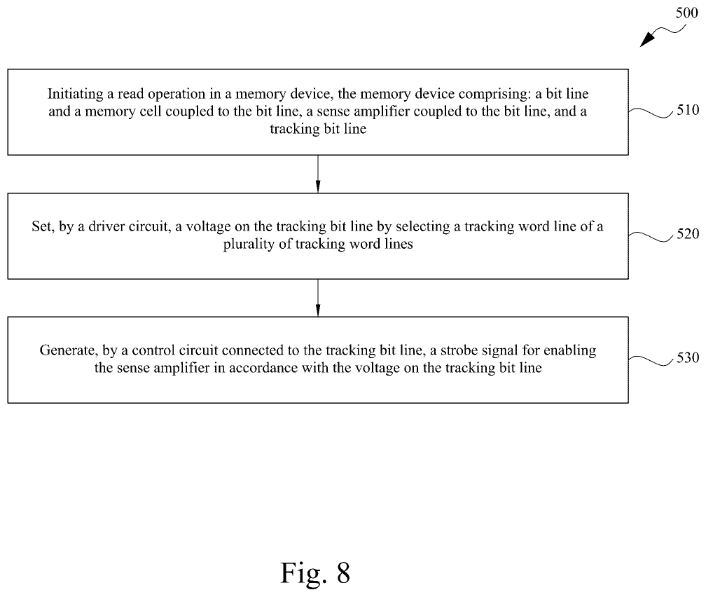

FIG. 8 is a flow diagram illustrating a method 500 for performing a read operation on memory device 10 in accordance with some embodiments. Method 500 may be performed by a system including a memory and a processor. In some examples, method 500 may be stored as instructions on a memory device, which when executed by a processor can cause the processor to perform method 500. Ways to implement the stages of method 500 will be described in greater detail below.

At stage 510 of method 500, a read operation is initiated on memory device 10. As discussed above, memory device 10 includes a bit line BL and memory cell 14 coupled to the bit line BL, sense amplifier 30 coupled to the bit line BL, and tracking bit line 80. The read operation is enabled by a memory controller.

At stage 520 of method 500, driver circuit, for example, replica word line driver circuit 55 sets a voltage on tracking bit line 80. As discussed above, the voltage on tracking bit line 80 is set by selecting one or the plurality of tracking word lines of memory device 10. In some examples, the voltage on tracking bit line 80 is set by varying a predetermined number of replica memory cells connected to the selected one of the plurality of tracking word lines.

At stage 530 of method 500, SAE control circuit 40 connected to tracking bit line 80 generates a strobe signal, that is, the SAE signal for enabling sense amplifier 30 in accordance with the voltage on tracking bit line 80. For example, and as discussed above SAE control circuit can compares the voltage on tracking bit line 80 with a reference voltage Vref and generates the SAE signal based on the comparison.

One or more embodiments achieve enhanced performance not only in read operations, but also in write operations. Specifically, characteristics of the memory cells and/or the bit lines contribute not only to read operation performance, but also to write operation performance. As a result, by tracking characteristics of the tracking cells and/or the tracking bit lines, which emulate corresponding characteristics of the memory cells and/or the bit lines in the same storage layer, one or more embodiments control not only read margin, but also write margin of the memory device.

In accordance with disclosed embodiments, a semiconductor device comprises: a memory array comprising a bit line and a memory cell coupled to the bit line; a sense amplifier coupled to the bit line; a tracking bit line; a driver circuit configured to control a voltage on the tracking bit line; and a control circuit connected to the tracking bit line, wherein the control circuit is configured to generate a strobe signal for enabling the sense amplifier in accordance with the voltage on the tracking bit line.

In accordance with further disclosed embodiments, a memory device comprises: a memory array comprising a bit line and a plurality of memory cells coupled to the bit line; a sense amplifier coupled to the bit line; a tracking array comprising: a tracking bit line, and a plurality of replica memory cells connected to the tracking bit line; a plurality of tracking word lines connected to the tracking array; a driver circuit configured to select one of the plurality of tracking word lines; and a control circuit connected to the tracking bit line, wherein the control circuit is configured to generate a strobe signal for enabling the sense amplifier in accordance with the voltage on the tracking bit line.

In accordance with still further disclosed embodiments, a method of performing a read operation on a memory device, the method comprising: initiating a read operation in a memory device, the memory device comprising: a bit line and a memory cell coupled to the bit line, a sense amplifier coupled to the bit line, and a tracking bit line; setting, by a driver circuit, a voltage on the tracking bit line by selecting a tracking word line of a plurality of tracking word lines; and generating, by a control circuit connected to the tracking bit line, a strobe signal for enabling the sense amplifier in accordance with the voltage on the tracking bit line.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a memory array comprising a bit line and a memory cell coupled to the bit line;
a sense amplifier coupled to the bit line;
a tracking bit line;
a driver circuit configured to control a voltage on the tracking bit line; and
a control circuit connected to the tracking bit line, wherein the control circuit is configured to generate a strobe signal for enabling the sense amplifier in accordance with the voltage on the tracking bit line.

2. The semiconductor device of claim 1, wherein the driver circuit comprises a replica word line driver circuit.

3. The semiconductor device of claim 1, further comprising:
a plurality of tracking word lines, wherein each of the plurality of tracking word lines are connected to a predetermined number of replica memory cells, and wherein the predetermined number of replica memory cells are connected to the tracking bit line.

4. The semiconductor device of claim 3, wherein each of the plurality of tracking word lines are of a different length.

5. The semiconductor device of claim 3, wherein a first predetermined number of replica memory cells connected to a first tracking word line is different than a second number of replica memory cells connected to a second tracking word line.

6. The semiconductor device of claim 3, wherein the driver circuit is configured to select one of the plurality of tracking word lines to control the voltage on the tracking bit line.

7. The semiconductor device of claim 3, wherein the driver circuit being configured to control the voltage on the tracking bit line comprises the driver circuit configured to control a read margin for the memory cell by controlling the voltage on the tracking bit line.

8. The semiconductor device of claim 1, further comprising:
a tracking array comprising a plurality of replica memory cells, each of the plurality of replica memory cells connected to the tracking bit line.

9. A memory device comprising:
a memory array comprising a bit line and a plurality of memory cells coupled to the bit line;
a sense amplifier coupled to the bit line;
a tracking array comprising:
a tracking bit line, and
a plurality of replica memory cells connected to the tracking bit line;
a plurality of tracking word lines connected to the tracking array;
a driver circuit configured to select one of the plurality of tracking word lines; and
a control circuit connected to the tracking bit line, wherein the control circuit is configured to generate a strobe signal for enabling the sense amplifier in accordance with the voltage on the tracking bit line.

10. The memory device of claim 9, wherein each of the plurality of tracking word lines are connected to a predetermined number of replica memory cells of the plurality of replica memory cells of the tracking array.

11. The memory device of claim 10, wherein a first predetermined number of replica memory cells connected to a first tracking word line is different than a second number of replica memory cells connected to a second tracking word line.

12. The memory device of claim 9, wherein each of the plurality of tracking word lines are of a different length.

13. The memory device of claim 9, wherein the driver circuit comprises a replica word line driver circuit.

14. The memory device of claim 9, wherein the driver circuit is configured to select one of the plurality of tracking word lines to control the voltage on the tracking bit line.

15. The memory device of claim 9, wherein the driver circuit is configured to select one of the plurality of tracking word lines to control a read margin for a memory cell connected to the bit line.

16. A method of performing a read operation on a memory device, the method comprising:
initiating a read operation in a memory device, the memory device comprising:
a bit line and a memory cell coupled to the bit line,
a sense amplifier coupled to the bit line, and
a tracking bit line;
setting, by a driver circuit, a voltage on the tracking bit line by selecting a tracking word line of a plurality of tracking word lines; and
generating, by a control circuit connected to the tracking bit line, a strobe signal for enabling the sense amplifier in accordance with the voltage on the tracking bit line.

17. The method of claim 16, wherein setting the voltage on the tracking bit line comprising selecting one of a plurality of tracking word line.

18. The method of claim 16, wherein setting the voltage on the tracking bit line comprising setting a read margin for the read operation.

19. The method of claim 16, wherein setting the voltage on the tracking bit line comprising setting a read margin for the read operation based on a select signal.

20. The method of claim 16, wherein each of the plurality of tracking word lines are connected with a number of replica memory cells of a tracking array.
